(19) United States
(12) Patent Application Publication
(10) Pub. No.: US 2022/0368146 A1
(43) Pub. Date: Nov. 17, 2022

(54) METHOD, CHARGING DEVICE, AND NON-TRANSITORY COMPUTER READABLE MEDIUM FOR DETECTING CHARGED STATE

(71) Applicants: HONGFUJIN PRECISION ELECTRONICS (ZHENGZHOU) CO., LTD., Zhengzhou (CN); HON HAI PRECISION INDUSTRY CO., LTD., New Taipei (TW)

(72) Inventors: GANG YANG, Zhengzhou (CN); JIAN-FENG SU, Zhengzhou (CN); FANG-YI ZHOU, Zhengzhou (CN)

(21) Appl. No.: 17/571,913

(22) Filed: Jan. 10, 2022

(30) Foreign Application Priority Data
May 11, 2021 (CN) 202110513652.5

(51) Int. Cl. H02J 7/00; H02J 50/80; G01R 31/3842

(52) U.S. Cl. CPC H02J 7/0049; H02J 7/00714; H02J 50/80; H02J 7/00032; H02J 7/007182; G01R 31/3842

(57) ABSTRACT

A method, charging device, and non-transitory computer readable medium for detecting charging state comparing obtaining data packages from a chargeable electrical device, each of the data packages comprising a first transmitting power; counting a quantity of the data packages of the first transmitting power data package being smaller than a theoretical transmitting power in a predetermined time period; and based on the quantity of the data packages, determining whether the chargeable electrical device is fully charged.

### CROSS-REFERENCE TO RELATED APPLICATIONS

This application claims priority to Chinese Patent Application No.

202110513652.5 filed on May 11, 2021, the contents of which are incorporated by reference herein.

### FIELD

The subject matter herein generally relates to wireless charging technology, and particularly to a method, a charging device, and a non-transitory computer readable medium for detecting charged state.

### BACKGROUND

Wireless charging technology is widely used in mobile phones, computers, wearable devices, medical equipment, and electromobiles. However, in some of the applications, a charging device and a chargeable electrical device work independently from each other, and lack any informational interaction. Thereby, the charging device may not obtain a charged state of the chargeable electrical device in time, and a charging efficiency of the chargeable electrical device may be affected.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a flowchart of at least one embodiment of a method for detecting charged state.

FIG. 2 illustrates a flowchart of another embodiment of such method.

FIG. 3 illustrates a block view of at least one embodiment of an apparatus for detecting charged state.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one.”

Furthermore, the term “module”, as used herein, refers to logic embodied in hardware or firmware, or to a collection of software instructions, written in a programming language, such as Java, C, or assembly. One or more software instructions in the modules can be embedded in firmware, such as in an EPROM. The modules described herein can be implemented as either software and/or hardware modules and can be stored in any type of non-transitory computer-readable medium or another storage device. Some non-limiting examples of non-transitory computer-readable media include CDs, DVDs, BLU-RAY, flash memory, and hard disk drives. The term “comprising” means “including, but not necessarily limited to”; it in detail indicates open-ended inclusion or membership in a so-described combination, group, series, and the like.

In at least one embodiment, a charging device may provide electrical power to a chargeable electrical device using wireless charging technology. A method for detecting charged state, in at least one embodiment, may be applied in an apparatus for detecting charged state. The apparatus for detecting charged state may be at least one charger as follows: an electromagnetic induction charger, a magnetic resonance charger, an electric field coupling charger, and/or a radio wave charger.

The chargeable electrical device may be any chargeable electrical terminal (“electrical device”) supporting wireless charging function. Such chargeable electrical device may include a battery, which may be a single battery or a battery pack. The chargeable electrical device may include but be not limited to a mobile phone, a tablet computer, a laptop computer, a personal computer (PC), an eBook reader, a working station, a server, a personal digital assistant (PDA), a portable multimedia player (PMP), a mobile medial equipment, a camera, a smart wearable device, a television, a gaming machine, a display device, etc. The smart wearable device may include an accessory function, such as a watch, a ring, a bracelet, an anklet, a necklace, a glasses, a contact lenses, or a head-mounted device (HMD), a fabric or clothing category, such as electronic clothing, an installation for the body, such as a skin pad or a tattoo, and a bioimplantable category, such as an implantable circuit.

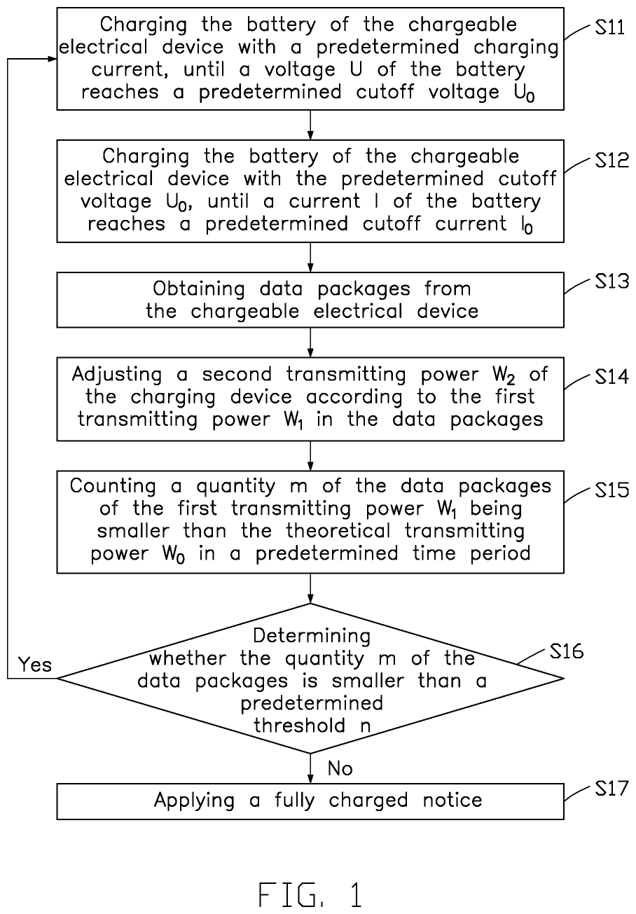

FIG. 1 illustrate at least one embodiment of a method for detecting charged state. The method is provided by way of example, as there are a variety of ways to carry out the method. Each block shown in FIG. 1 represents one or more processes, methods, or subroutines carried out in the example method. Furthermore, the illustrated order of blocks is by example only and the order of the blocks can be changed. Additional blocks may be added or fewer blocks may be utilized, without departing from this disclosure. The example method can begin at block S11.

At block S11, charging the battery of the chargeable electrical device with a predetermined charging current, until a voltage U of the battery reaches a predetermined cutoff voltage U0.

In at least one embodiment, transmitting energy between the charging device and the chargeable electrical device, the charging device transmits an energy signal, the chargeable electrical device receives the energy signal for charging the battery. The energy transmission between the charging device and the chargeable electrical device may be in at least one way of electro-magnetic induction, magnetic resonance, electric field coupling, and/or radio wave.

In at least one embodiment, the energy signal includes the predetermined charging current and the predetermined cutoff voltage U0. In at least one embodiment, the predetermined charging current may be about 0.5 C˜3.0 C, preferably, the predetermined charging current may be about 0.5 C˜1.0 C. The predetermined cutoff voltage U0 may be about 4.0V˜4.2V, preferably, the predetermined cutoff voltage U0 may be 4.1V, 4.15V, or 4.2V. The charging device charges the battery of the chargeable electrical device by constant current. During the constant current charging, a capacity of the battery gradually increases, the voltage U of the battery gradually increases accordingly.

In at least one embodiment, the capacity of the battery means quantity of electric charge or state of charge (SOC).

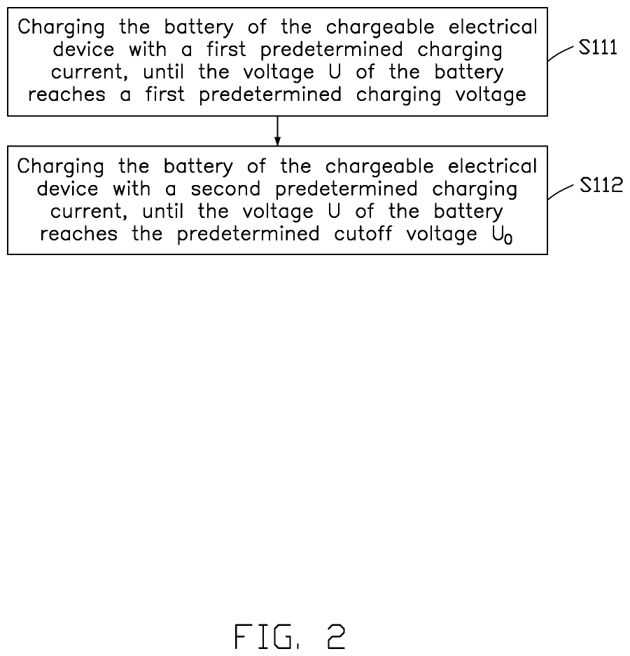

In other embodiments, referring to FIG. 2, block S11 may include:

At block S111, charging the battery of the chargeable electrical device with a first predetermined charging current, until the voltage U of the battery reaches a first predetermined charging voltage.

In at least one embodiment, the first predetermined charging current may be about 0.5 C˜3.0 C. The first predetermined charging voltage may be about 2.0V˜4.0V.

At block S112, charging the battery of the chargeable electrical device with a second predetermined charging current, until the voltage U of the battery reaches the predetermined cutoff voltage U0.

The second predetermined charging current is smaller than the first predetermined charging current. The predetermined cutoff voltage U0 is greater than the first predetermined charging voltage.

In at least one embodiment, the energy signal includes the first predetermined charging current, the second predetermined charging current, the first predetermined charging voltage, and the predetermined cutoff voltage U0. The charging device charges the battery of the chargeable electrical device by constant current charging in stages.

In other embodiments, the constant current charging may include two or more stages. The predetermined charging current gradually decreases, the predetermined charging voltage gradually increases accordingly. In a last stage, the voltage U of the battery reaches the predetermined cutoff voltage U0.

At block S12, charging the battery of the chargeable electrical device with the predetermined cutoff voltage U0, until a current I of the battery reaches a predetermined cutoff current I0.

In at least one embodiment, the energy signal includes the predetermined cutoff current I0. In at least one embodiment, the predetermined cutoff current I0 may be about 0.05 C˜0.2 C. The charging device charges the battery of the chargeable electrical device by constant voltage charging. During the constant voltage charging, the current I input into the battery gradually decreases.

At block S13, obtaining data packages from the chargeable electrical device.

In at least one embodiment, the chargeable electrical device transmits the data packages to the charging device, the charging device receives the data packages. The chargeable electrical device may transmit the data packages to the charging device in real time or at time intervals.

Each of the data packages includes information as to first transmitting power W1. The first transmitting power W1 is relative to the energy signal received by the chargeable electrical device. In at least one embodiment, the first transmitting power W1 may be about 500 mW˜2000 mW.

For instance, during the constant current charging, the energy signal includes the predetermined charging current. The first transmitting power W1 and the predetermined charging current are in positive correlation. The predetermined charging current increases, and the first transmitting power W1 increases accordingly. Determining a value of the predetermined charging current is by reference to determining a value of the first transmitting power W1. During the constant current charging, the first transmitting power W1 remains unchanged.

For instance, during a constant voltage charging, the energy signal includes the predetermined cutoff voltage U0. The first transmitting power W1 and the predetermined cutoff voltage U0 are in positive correlation. When the predetermined cutoff voltage U0 increases, the first transmitting power W1 increases accordingly.

In at least one embodiment, the first transmitting power W1 meets: W1>U0*I. Since attenuation may occur during the transmission of the energy signal, the first transmitting power W1 that the chargeable electrical device transmits to the charging device is greater than a theoretical transmitting power W0 of the chargeable electrical device. The theoretical transmitting power W0 meets: W0=U0*I.

During the constant voltage charging, the predetermined cutoff voltage U0 remains unchanged, the first transmitting power W1 and the current I of the battery are in positive correlation. When the current I stored in the battery decreases, the first transmitting power W1 decreases accordingly.

At block S14, adjusting a second transmitting power W2 of the charging device according to the first transmitting power W1 indicated in the data package.

In at least one embodiment, the charging device receives the data package and obtains the first transmitting power W1 in the data package. The charging device adjusts the second transmitting power W2 according to the first transmitting power W1, so as to adjust the energy signal that transmitted to the chargeable electrical device. The second transmitting power W2 is a signal transmitting power of the charging device.

The second transmitting power W2 is greater than the first transmitting power W1. The second transmitting power W2 and the first transmitting power W1 are in positive correlation.

During the constant current charging, the first transmitting power W1 remains unchanged, the second transmitting power W2 also remains unchanged. During the constant voltage charging, when the first transmitting power W1 decreases, the second transmitting power W2 decreases accordingly.

At block S15, counting a quantity (“m”) of the data packages of the first transmitting power W1 being smaller than the theoretical transmitting power W0 within a predetermined time period.

In at least one embodiment, the theoretical transmitting power W0 may be about 500 mW˜1000 mW. The predetermined time period may be about 30s˜1800s, preferably, the predetermined time period is 900 s.

In at least one embodiment, the charging device receives the data packages and defines all the received data packages as a first data package, and defines data packages meeting the condition as follows, namely, in a second data package, the first transmitting power W1 is smaller than the theoretical transmitting power W0. The charging device counts a quantity m of the second data package in the predetermined time period.

At block S16, determining whether the quantity m of the data packages is smaller than a predetermined threshold (“n”). If m<n, the method goes back to block S11. If m≥n, the method goes to block S17.

In at least one embodiment, the predetermined threshold n may be about 855˜1710. The predetermined threshold n is relative to a proportion of the second data package in the predetermined time period. The proportion of the second data package means the ratio between the quantity m of the second data package and the quantity of the first data package. In at least one embodiment, the proportion of the second data package may be about 95%˜100%.

In at least one embodiment, when the quantity m of the second data package is greater than or equal to the predetermined threshold n, the charging device will determine that the chargeable electrical device is fully charged. When the quantity m of the second data package is smaller than the predetermined threshold n, the charging device will determine that the chargeable electrical device is not fully charged. In at least one embodiment, when the charging device determines that the chargeable electrical device is not fully charged, charging of the battery of the chargeable electrical device is continued.

In a test, the predetermined time period may be 1800 s, the theoretical transmitting power W0=1000 mW, the predetermined threshold n=1710. The charging device receives and calculates the quantity m of the second data package as being m=1800 in 1800 s. Since m>n, at this time, the charging device determines that the chargeable electrical device is fully charged.

In at least one embodiment, to prevent any errors caused by power fluctuations during the charging, the charging device may dynamically adjust at least one of the predetermined time period, the theoretical transmitting power W0, and the predetermined threshold n accordance with a determination-accuracy rating.

At block S17, applying a fully charged notice.

In at least one embodiment, after the charging device determines that the chargeable electrical device is fully charged, the charging device applies a fully charged notice, such as changing a status of an indicator, a buzzer warning, turning to a sleep mode or shutting down, so as to notify the user that charging of the chargeable electrical device is completed.

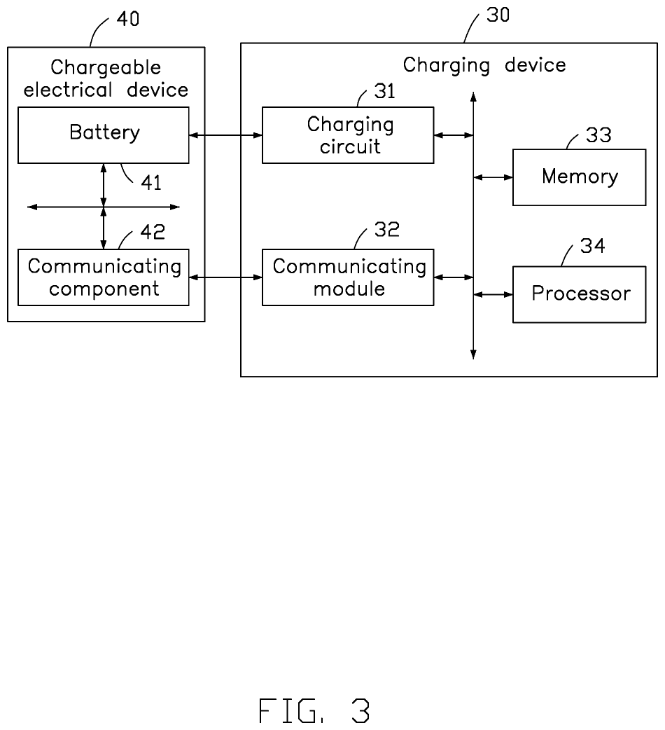

FIG. 3 illustrates at least one embodiment of a charging device 30. The charging device 30 includes a charging circuit 31, a communicating module 32, a memory 33, and at least one processor 34. The charging circuit 31 is configured to charge a battery 41 of the chargeable electrical device 40. The communicating module 32 is configured to communicate and exchange data with a communicating component 42 of the chargeable electrical device 40. The memory 33 is configured to store computer programs, which can be processed by the processor 34 to perform the method for detecting charged state, such as blocks S11 to S17 and S111 to S112 of the method for detecting charged state. The charging circuit 31, the communicating module 32, the memory 33, and the at least one processor 34 may be electrically connected to each other through interfaces or a bus. The battery 41 and the communicating component 42 may be electrically connected to each other through interfaces or a bus.

The charging circuit 31 wirelessly charges the battery 41 of the chargeable electrical device 40 by transmitting energy signals. In at least one embodiments, the wireless charging may include at least one of the electromagnetic induction, the magnetic resonance, the electric field coupling, and/or the radio wave.

The communicating module 32 is configured to wirelessly communicate and exchange data with the communicating component 42 of the chargeable electrical device 40. In at least one embodiments, the wireless communication may include at least one of WI-FI, BLUETOOTH, ZIGBEE, and/or Near Field Communication (NFC).

In at least one embodiment, the memory 33 can include various types of non-transitory computer-readable storage mediums. For example, the memory 33 can be an internal storage system, such as a flash memory, a random access memory (RAM) for the temporary storage of information, and/or a read-only memory (ROM) for permanent storage of information. The memory 33 can also be an external storage system, such as a hard disk, a storage card, or a data storage medium.

In at least one embodiment, the processor 34 can be a central processing unit (CPU), a microprocessor, a digital signal processor (DSP), an application specific integrated circuit (ASIC), a field-programmable gate array (FPGA), a data processor chip, a programmable logic device (PLD), a discrete gate/transistor logic device, or a discrete hardware component. The processor 34 may be electrically connected to other elements of the charging device 30 through interfaces or a bus. In at least one embodiment, the charging device 30 includes a plurality of interfaces configured to communicate with other devices or apparatus.

In at least one embodiment, the charging device 30 may include more or less components, modules, circuits, elements, or assemblies other than the modules shown in the figures.

In at least one embodiment, the charging device 30 and the chargeable electrical device 40 may exchange information and/or data by wireless communication. The charging device 30 receives information as to the first transmitting power from the chargeable electrical device 40, counts the first transmitting power as being smaller than the theoretical transmitting power in the predetermined time period, so as to determine whether the chargeable electrical device 40 is fully charged, and monitor the charged state of the chargeable electrical device 40 in real time.

In at least one embodiment, the computer program can be non-transitory computer program medium integrated in the memory 33 and processed by the least one processor 34 to perform the method for detecting charged state shown in FIGS. 1-2.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being embodiments of the present disclosure.

What is claimed is:

1. A method for detecting charged state comprising:
obtaining data packages from a chargeable electrical device, each of the data packages comprising a first transmitting power;
counting a quantity of the data packages of the first transmitting power being smaller than a theoretical transmitting power in a predetermined time period; and
based on the quantity of the data packages, determining whether the chargeable electrical device is fully charged.

2. The method according to claim 1, wherein the based on the quantity of the data packages, determining whether the chargeable electrical device is fully charged comprises:
if the quantity of the data packages is greater than or equal to a predetermined threshold, determining that the chargeable electrical device is fully charged.

3. The method according to claim 2, wherein after determining that the chargeable electrical device is fully charged, the method further comprises:
applying a fully charged notice.

4. The method according to claim 1, wherein before the obtaining the data packages from the chargeable electrical device, the method further comprises:
charging a battery of the chargeable electrical device with a predetermined charging current, until a voltage of the battery reaches a predetermined cutoff voltage; the first transmitting power and the predetermined charging current are in positive correlation.

5. The method according to claim 4, wherein after the charging the battery of the chargeable electrical device with the predetermined charging current, until the voltage of the battery reaches the predetermined cutoff voltage, the method further comprises:
charging the battery of the chargeable electrical device with the predetermined cutoff voltage, until a current of the battery reaches a predetermined cutoff current; the first transmitting power and the predetermined cutoff current are in positive correlation.

6. The method according to claim 5, wherein the first transmitting power meets: W1>U0*I, the W1 is the first transmitting power, the I is the current of the battery, and the U0 is the predetermined cutoff voltage.

7. The method according to claim 1, wherein after the obtaining the data packages from the chargeable electrical device, the method further comprises:
adjusting a second transmitting power of a charging device according to the first transmitting power in the data package; the second transmitting power and the first transmitting power are in positive correlation.

8. The method according to claim 1, wherein the based on the quantity of the data packages, determining whether the chargeable electrical device is fully charged comprises:
if the quantity of the data packages is smaller than a predetermined threshold, determining that the chargeable electrical device is not fully charged and continuously charging the battery of the chargeable electrical device.

9. A charging device comprising:
a charging circuit, configured to charge a battery of a chargeable electrical device;
at least one processor; and
at least one memory coupled to the at least one processor and storing program instructions; the at least one memory and the program instructions configured to, with the at least one processor, cause the charging device to perform:
obtaining data packages from the chargeable electrical device, each of the data packages comprising a first transmitting power;
counting a quantity of the data packages of the first transmitting power being smaller than a theoretical transmitting power in a predetermined time period; and
based on the quantity of the data packages, determining whether the chargeable electrical device is fully charged.

10. The charging device according to claim 9, wherein the based on the quantity of the data packages, determining whether the chargeable electrical device is fully charged comprises:
if the quantity of the data packages is greater than or equal to a predetermined threshold, determining that the chargeable electrical device is fully charged.

11. The charging device according to claim 10, wherein after determining that the chargeable electrical device is fully charged, the at least one memory and the program instructions configured to, with the at least one processor, cause the charging device to further perform:
applying a fully charged notice.

12. The charging device according to claim 9, wherein before the obtaining the data packages from the chargeable electrical device, the at least one memory and the program instructions configured to, with the at least one processor, cause the charging device to further perform:
charging a battery of the chargeable electrical device with a predetermined charging current, until a voltage of the battery reaches a predetermined cutoff voltage; the first transmitting power and the predetermined charging current are in positive correlation.

13. The charging device according to claim 12, wherein after the charging the battery of the chargeable electrical device with the predetermined charging current, until the voltage of the battery reaches the predetermined cutoff voltage, the at least one memory and the program instructions configured to, with the at least one processor, cause the charging device to further perform:
charging the battery of the chargeable electrical device with the predetermined cutoff voltage, until a current of the battery reaches a predetermined cutoff current; the first transmitting power and the predetermined cutoff current are in positive correlation.

14. The charging device according to claim 13, wherein the first transmitting power meets: W1>U0*I, the W1 is the first transmitting power, the I is the current of the battery, and the U0 is the predetermined cutoff voltage.

15. The charging device according to claim 9, wherein after the obtaining the data packages from the chargeable electrical device, the at least one memory and the program instructions configured to, with the at least one processor, cause the charging device to further perform:
adjusting a second transmitting power of the charging device according to the first transmitting power in the data package; the second transmitting power and the first transmitting power are in positive correlation.

16. The charging device according to claim 9, wherein the based on the quantity of the data packages, determining whether the chargeable electrical device is fully charged comprises:
if the quantity of the data packages is smaller than a predetermined threshold, determining that the chargeable electrical device is not fully charged and continuously charging the battery of the chargeable electrical device.

17. A non-transitory computer readable medium comprising program instructions for causing a charging device to perform at least the follow:
obtaining data packages from a chargeable electrical device, each of the data packages comprising a first transmitting power;
counting a quantity of the data packages of the first transmitting power being smaller than a theoretical transmitting power in a predetermined time period; and
based on the quantity of the data packages, determining whether the chargeable electrical device is fully charged.
